(19) United States
(12) Patent Application Publication
(10) Pub. No.: US 2019/0023049 A1
(43) Pub. Date: Jan. 24, 2019

(54) METHOD FOR FORMING THREE-DIMENSIONAL PATTERN AND PRODUCT OBTAINED THEREBY

(71) Applicant: 3MACJET TECHNOLOGY CO., LTD., TAINAN CITY (TW)

(72) Inventors: YUNG-HSIEN LU, TAINAN CITY (TW); RUEI-MING HUANG, TAINAN CITY (TW)

(21) Appl. No.: 15/674,913

(22) Filed: Aug. 11, 2017

(30) Foreign Application Priority Data
Jul. 20, 2017 (TW) 106124384

(51) Int. Cl. B41M 7/00; B41M 5/00; B41M 5/46; B41M 3/00; H05K 3/20; H05K 3/26

(52) U.S. Cl. CPC B41M 7/0045; B41M 7/0018; B41M 5/0029; H05K 3/26; B41M 3/006; H05K 3/207; B41M 5/46

(57) ABSTRACT

The present invention relates to a method for forming three-dimensional (3D) patterns and products obtained thereby, especially to a method for forming three-dimensional patterns and products obtained thereby in which ink is coated on surface of a transparent substrate by an inkjet printer to form at least one layer of inkjet-printed pattern on the surface of the transparent substrate. Moreover, the transparent substrate is also sprayed with a reflective bottom layer covered over the inkjet-printed pattern. Thereby the inkjet-printed pattern is formed on the transparent substrate by the inkjet printer quickly and easily. A shiny and beautiful 3D effect is generated by the inkjet-printed pattern with a certain thickness and reflection of the reflective bottom layer. Thereby consumers are attracted to purchase related products and the industry's competitiveness is enhanced.

### BACKGROUND OF THE INVENTION

### Field of the Invention

The present invention relates to a method for forming three-dimensional (3D) patterns and products obtained thereby, especially to a method for forming 3D patterns and products obtained thereby in which the 3D patterns are formed on a transparent substrate by an inkjet printer rapidly.

### Description of Related Art

With rapid development of electronic technology, there is always a brand new portable electronic such as a mobile phone, a personal digital assistant, a tablet computer and a notebook computer available on the market. In order to draw consumer's attention, mobile phone manufacturers in the business are dedicated to not only improving functions of the electronics but also developing various accessories.

A mobile phone case is used to cover over the mobile phone for protection against scratches and abrasions so that the mobile phone case is widely used and well received by consumers. However, the design of the mobile phone case focuses on the protection function. Thus most of the appearance of the mobile phone case is monotonous and boring such as the case with a single color or the transparent case. For consumers that love novel and fashion design, the single-color or transparent mobile phone case is unable to meet their requirements. Thereby services including attachment of crystal or painting of patterns are provided to improve the overall aesthetics. The patterns can be coated on the mobile phone case by several ways now including hand drawing, transfer printing, inkjet printing, etc. The hand drawing not only takes time but also results in difference in quality due to techniques of the staff. As to the patterns generated by transfer printing and inkjet printing, they are monotonous, flat, and lack of delicacy and sense of aesthetics. Thus the consumers don't want to buy the product.

Thus there is room for improvement and there is a need to provide a novel method and products obtained thereby for overcoming the above shortcomings of the methods and the products available now.

### SUMMARY OF THE INVENTION

Therefore it is a primary object of the present invention to provide a method for forming three-dimensional (3D) patterns and products obtained thereby in which 3D patterns are formed on a transparent substrate quickly by an inkjet printer.

In order to achieve the above object, a method for forming three-dimensional (3D) patterns according to the present invention includes a plurality of steps. First prepare a transparent substrate. Dry the transparent substrate after the transparent substrate being washed and cleaned. Then coat ink on a surface of the clean and dry transparent substrate by an inkjet printer and dry the ink to form a layer of inkjet-printed pattern. Thus at least one layer of the inkjet-printed pattern is formed on the surface of the transparent substrate and the total thickness of the at least one layer of the inkjet-printed pattern is ranging from 5 μm to 250 μm. Next at least one reflective bottom layer is sprayed on one surface of the transparent substrate with the inkjet-printed pattern. Thus the reflective bottom layer is covered over the inkjet-printed pattern.

There is a plurality of layers of the inkjet-printed pattern formed on the surface of the transparent substrate.

The ink used is ultraviolet (UV) cured ink. An UV device is used to emit UV light to the UV cured ink for drying the UV cured ink immediately after the UV cured ink being coated on the surface of the transparent substrate by the inkjet printer.

The ink used is common ink formed by pigments mixed with solvents. A heating plate is disposed under the transparent substrate and used to heat the transparent substrate to a preset temperature. Thus the solvents contained in the ink are evaporated faster once the ink from the inkjet printer is in contact with the surface of the transparent substrate and the ink is dried rapidly.

The transparent substrate is heated up to 30-80° C. by the heating plate.

A product obtained by the method for forming 3D patterns includes a transparent substrate, at least one layer of inkjet-printed pattern connected to a surface of the transparent substrate and at least one reflective bottom layer connected to the surface of the transparent substrate with the inkjet-printed pattern and covered over the inkjet-printed pattern. The total thickness of the at least one layer of the inkjet-printed pattern is 5 μm to 250 μm.

In the product obtained by the method for forming 3D patterns, there is a plurality of layers of the inkjet-printed pattern stacked correspondingly.

The transparent substrate is made from glass.

The transparent substrate can be a cell phone case, a housing of consumer electronics or a dashboard.

Thereby the inkjet-printed patterns are formed on the transparent surface simply and quickly by the inkjet printer. The inkjet-printed patterns have a certain thickness and the reflective bottom layer is used to reflect light passed through the inkjet-printed patterns. Thus the dazzling and beautiful patterns with 3D shimmer are provided. Thereby the 3D patterns that shimmer attract consumers who are willing to buy and the industry's competitiveness is ensured.

### BRIEF DESCRIPTION OF THE DRAWINGS

The patent or application file contains at least one drawing executed in color. Copies of this patent or patent application publication with color drawings) will be provided by the Office upon request and payment of the necessary fee.

The structure and the technical means adopted by the present invention to achieve the above and other objects can be best understood by referring to the following detailed description of the preferred embodiments and the accompanying drawings, wherein:

FIG. 1 is a flow chart of an embodiment according to the present invention;

FIGS. 2(A)-2(E) are schematic drawings showing a flow chart of an embodiment according to the present invention;

FIGS. 3(A)-3(E) are schematic drawings showing a flow chart of another embodiment according to the present invention;

FIG. 4 is a sectional view of an embodiment according to the present invention;

FIG. 5 is a photograph of an embodiment of a method for forming three-dimensional (3D) patterns applied to a cell phone case according to the present invention;

FIG. 6 is a partial enlarged view of a photograph of an embodiment of a method for forming 3D patterns applied to a cell phone case according to the present invention;

FIG. 7 is a photograph of an embodiment of a method for forming 3D patterns applied to another cell phone case according to the present invention;

FIG. 8 is a photograph of an embodiment of a method for forming 3D patterns applied to a back cover of tablet computer according to the present invention.

### DETAILED DESCRIPTION OF THE PREFERRED EMBODIMENT

In order to learn technical content and functions of the present invention clearly, please refer to the following detailed descriptions, the figure and the reference numbers of components.

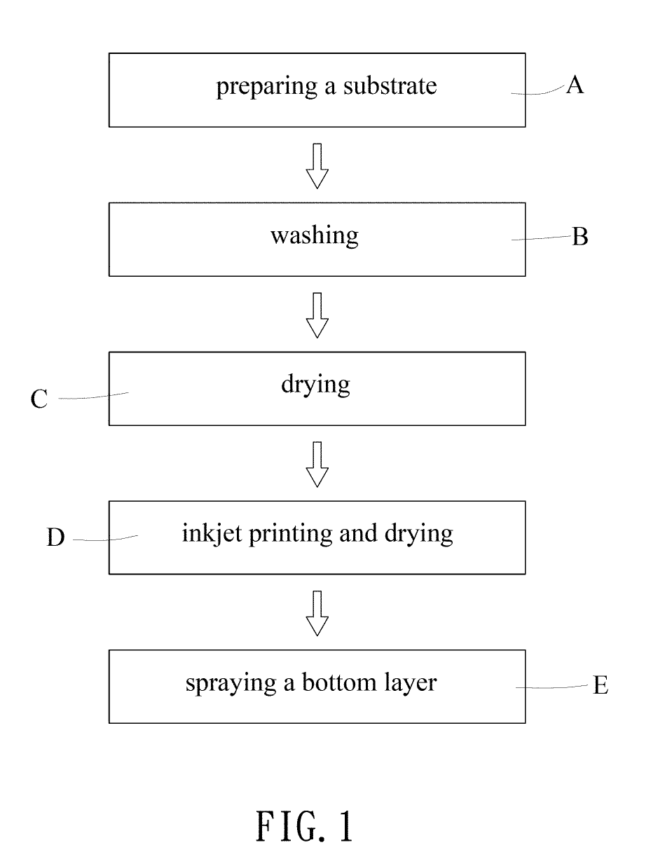

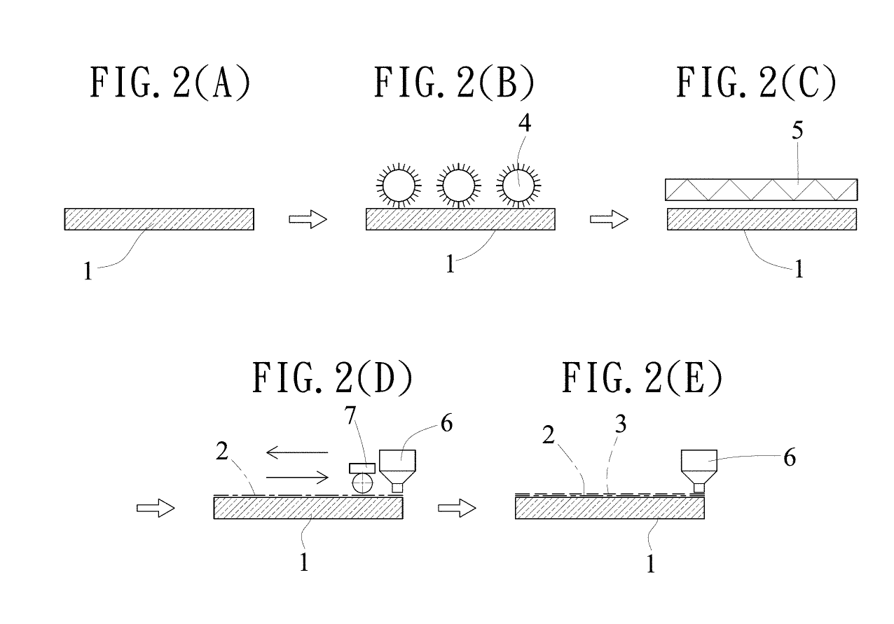

Refer to FIG. 1 and FIGS. 2(A)-2(E), a according to the present invention includes the following steps:

A preparing a substrate: prepare a transparent substrate 1 mainly made from glass such as a cell phone case made from glass.

B washing: set the transparent substrate 1 in an automatic cleaning device in which oil on surface of the transparent substrate 1 is removed by using a roller brush 4 with degreasant or detergent and then the surface of the transparent substrate 1 is washed and cleaned by pure water.

C drying: place the cleaned transparent substrate 1 in a heating device 5 such as an oven for drying or air thy the cleaned transparent substrate 1 at room temperature.

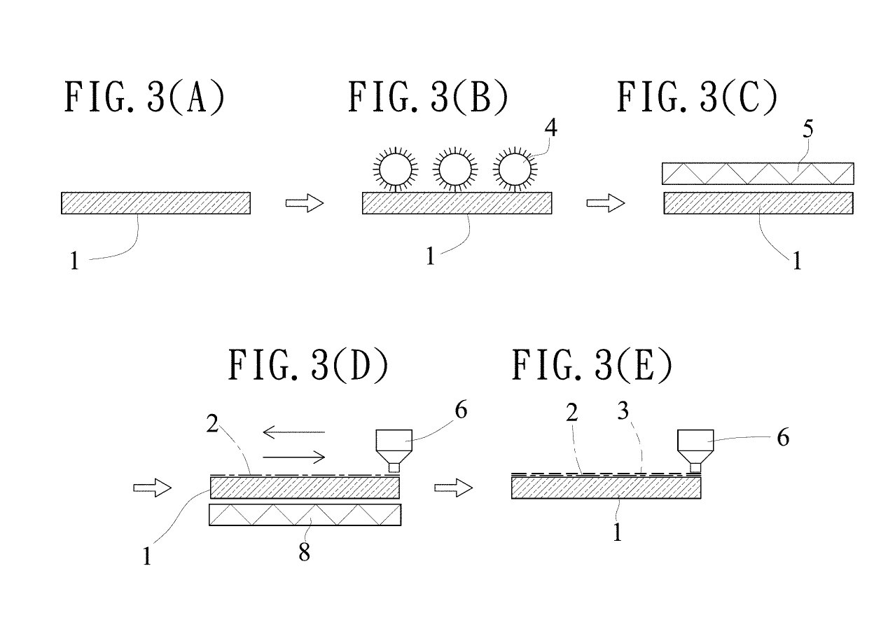

D inkjet printing and drying: set the cleaned and dried transparent substrate 1 in a clean space and coat ultraviolet (UV) cured ink on surface of the transparent substrate 1 by a inkjet printer 6; then immediately dry the UV cured ink on the surface of the transparent substrate 1 by an UV device 7 that emits UV light to the UV cured ink so as to form a layer of inkjet-printed pattern 2 on the surface of the transparent substrate 1. Thereby at least one layer of the inkjet-printed pattern 2 is formed on the surface of the transparent substrate 1 by the step of drying the UV cured ink after the UV cured ink being coated on surface of the transparent substrate 1. A plurality of layers of the inkjet-printed pattern 2 is stacked over the surface of the transparent substrate 1 by jet printing in turn in an embodiment of the present invention and the total thickness of the at least one layer of the inkjet-printed pattern 2 is ranging from about 5 μm to 250 μm. Also refer to FIGS. 3(A)-3(E), the transparent substrate 1 is heated up to 30-80° C. by a heating plate 8 thereunder while common ink formed by pigments mixed with solvents is coated on the surface of the transparent substrate 1 by a inkjet printer 6. The solvents contained in the ink are evaporated faster once the ink from the inkjet printer 6 is in contact with the surface of the transparent substrate 1. Thereby the inkjet printing process and the drying process are carried out at the same time to increase the thickness of the inkjet-printed pattern 2 stacked over the transparent substrate 1.

E spraying a bottom layer: spray at least one reflective bottom layer 3 on one side of the transparent substrate 1 with the inkjet-printed pattern 2 by an inkjet printer 6 or a screen printer after the inkjet-printed pattern 2 with a certain thickness being coated on the surface of the transparent substrate 1. Thus the reflective bottom layer 3 is covered over the inkjet-printed pattern 2. The reflective bottom layer 3 can be a highly reflective paint or a light color paint.

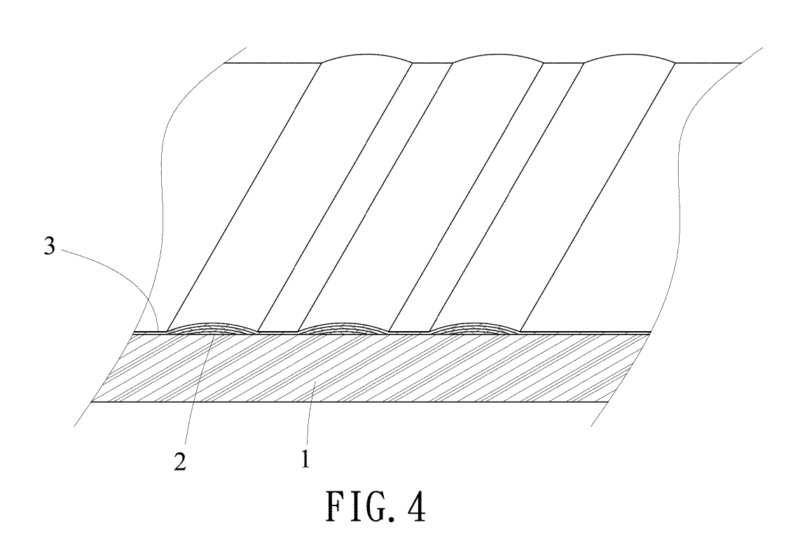

As shown in FIG. 4, the method for forming 3D patterns of the present invention can produce products with 3D patterns quickly and rapidly while the product includes a transparent substrate 1, at least one layer of inkjet-printed pattern 2 connected to the surface of the transparent substrate 1, and at least one reflective bottom layer 3 connected to the surface of the transparent substrate 1 with the inkjet-printed pattern 2 and covered over the inkjet-printed pattern 2.

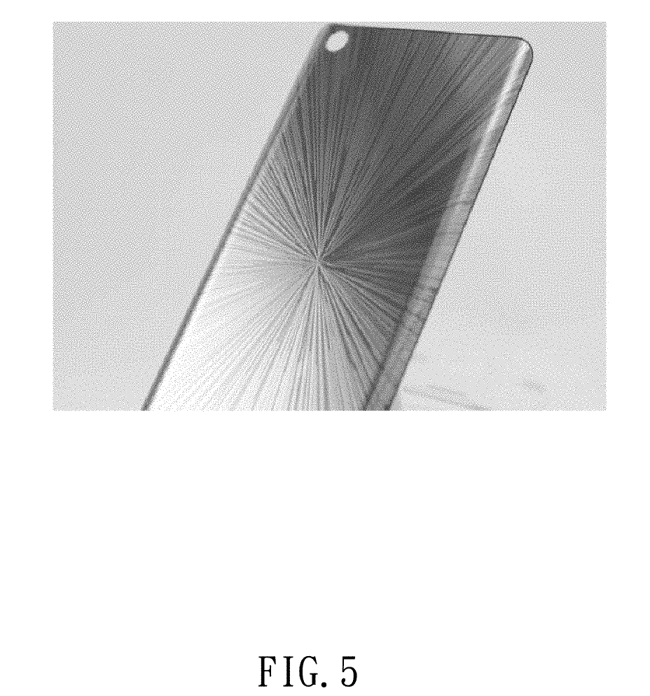

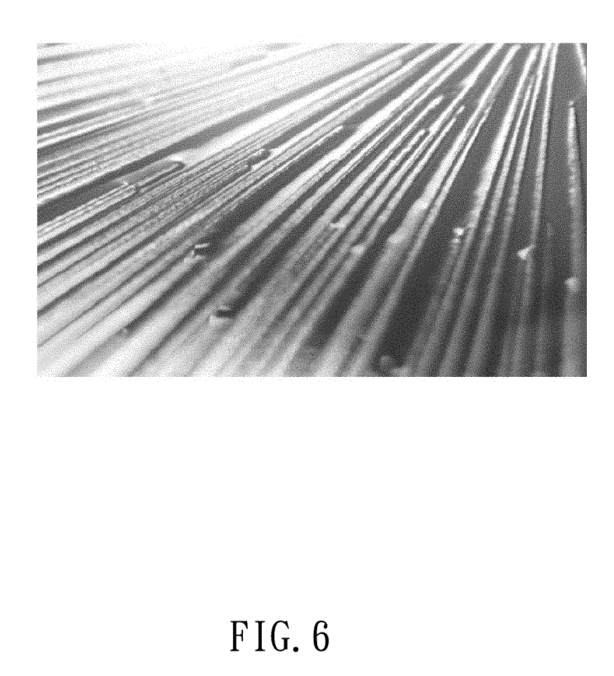

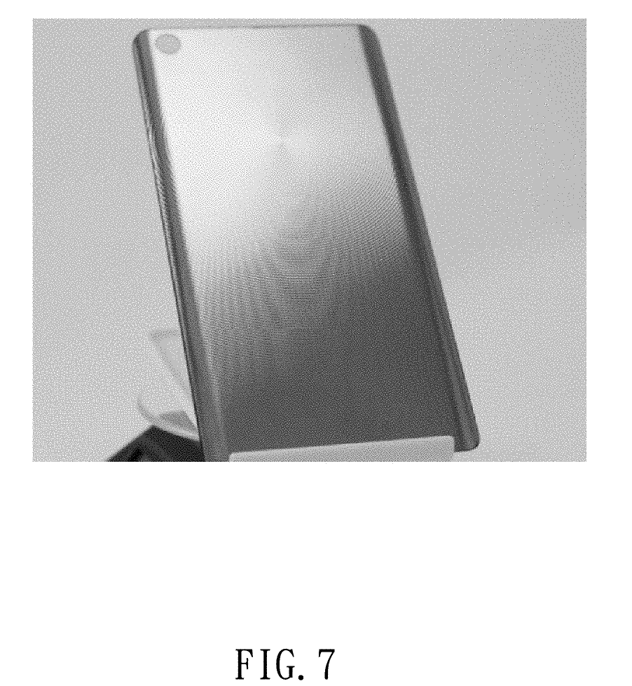

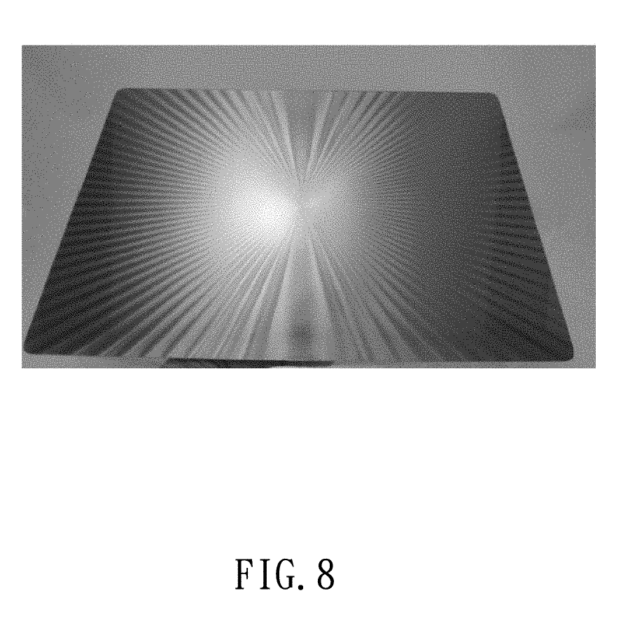

Thereby the product with 3D patterns according to the present invention includes the inkjet-printed pattern 2 with a certain thickness and the reflective bottom layer 3. The light passed through gaps of the inkjet-printed pattern 2 is emitted to and reflected by the reflective bottom layer 3. As to the light emitted to the inkjet-printed pattern 2, it passes the inkjet-printed pattern 2 first and then projects to the reflective bottom layer 3. The inkjet-printed pattern 2 includes a thicker central part and a gradually-thinner periphery part owing to surface tension. Thus different amount of light is passed through various parts of the inkjet-printed pattern 2 with different thickness when the light projected to and reflected by the reflective bottom layer 3 is emitted to the inkjet-printed pattern 2 again. Therefore a shiny 3D effect is formed as shown in the FIG. 5 to FIG. 8. In the figures, a cell phone case produced by the present method for forming 3D patterns includes patterns with 3D glitters obviously. The overall aesthetics and dazzling sense of the glass product such as the cell phone case are improved. Moreover, the present invention uses the inkjet printer 6 to coat the inkjet-printed pattern 2 on the surface of the transparent substrate 1. While in use, the amount of the ink, used by the inkjet printer 6, and the figures and colors of the inkjet-printed pattern 2 can, be set by the computer connected to the inkjet printer 6. Thus the formation of the figures is rapid and the quality of the product is uniform. The products are made easily even users have no professional drawing technique so that the labor cost is saved. The ink is dried immediately after being coated on the surface of the transparent substrate 1 by the inkjet printer 6. Thus the diffusion and mixing of the upper layer of the inkjet-printed pattern 2 with the lower layer of the inkjet-printed pattern 2 can be avoided. The next layer of the inkjet-printed pattern 2 is coated shortly after the previous layer of the inkjet-printed pattern 2 being printed on the transparent substrate 1. Thus the production efficiency is improved.

Besides the cell phone case, the transparent substrate 1 of the present invention can be a dashboard, and a housing or consumer electronics such as a mobile phone, a portable media player, a notebook computer, a tablet computer, etc.

According to the structure and applications mentioned above, the present invention has the following advantages:
1. The present method for forming 3D patterns and products obtained thereby mainly uses the inkjet printer to form patterns on the transparent substrate. Thus patterns, colors and thickness going to be inkjet-printed can be set by the computer connected to the inkjet printer. Thereby the patterns are formed rapidly and the quality of the product is uniform. Even users without professional drawing techniques can make the patterns and the products easily. Thus the cost required for hiring an employee with professional drawing techniques is saved.
2. The ink is dried immediately after being coated on the surface of the transparent substrate by the inkjet printer. Thus the diffusion and mixing of the upper and the lower layers of the inkjet-printed pattern caused by the inkjet-printed pattern that has not dried yet can be avoided. The next layer of the inkjet-printed pattern is coated right after the previous layer of the inkjet-printed pattern being printed on the transparent substrate so that the production efficiency is improved.
3. There is a plurality of layers of the inkjet-printed pattern so that the inkjet-printed pattern has a certain thickness. Different amount of light is passed through the inkjet-printed pattern with different thickness after being reflected by the reflective bottom layer and projected to the inkjet-printed pattern. Thus a shiny 3D effect is provided. The overall aesthetics and dazzling sense of the product are improved. Thus the consumers would like to purchase the product, the sales rate is high and the competitiveness is increased.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A method for forming three-dimensional (3D) patterns comprising:
preparing a transparent substrate and drying the transparent substrate subsequent to the transparent substrate being washed and cleaned;
coating ink on a surface of the clean and dry transparent substrate by an inkjet printer and curing the ink immediately to form a layer of inkjet-printed pattern; and
spraying at least one reflective bottom layer on one side of the transparent substrate with the inkjet-printed pattern by the inkjet printer, the reflective bottom layer thereby covering the inkjet-printed pattern, the reflective bottom layer being a highly-reflective paint;
wherein at least one layer of the inkjet-printed pattern is formed on the surface of the transparent substrate by curing the ink immediately subsequent to coating ink on the surface of the transparent substrate; and total thickness of the at least one layer of the inkjet-printed pattern is greater than 5 μm and not more than 250 μm.

2. The method as claimed in claim 1, wherein a plurality of layers of the inkjet-printed pattern stacked correspondingly is formed on the surface of the transparent substrate.

3. The method as claimed in claim 1, wherein the ink is cured by a device emitting UV light to the ink immediately after being coated on the surface of the transparent substrate by the inkjet printer.

4. The method as claimed in claim 1, wherein the ink is common ink formed by pigments mixed with solvents; a heating plate is disposed under the transparent substrate and used to heat the transparent substrate to a preset temperature; thus the solvents contained in the ink are evaporated when the ink from the inkjet printer is in contact with the surface of the transparent substrate.

5. The method as claimed in claim 4, wherein the transparent substrate is heated up to 30-80° C. (degrees Celsius) by the heating plate.

6. A product obtained by a method for forming three-dimensional (3D) patterns, comprising:
producing a dried-and-cleaned transparent substrate by preparing a transparent substrate and drying the transparent substrate subsequent to washing and cleaning the transparent substrate;
forming a layer of inkjet-printed pattern by coating ink on a surface of the dried-and-cleaned transparent substrate by an inkjet printer and curing the ink immediately, wherein at least one layer of the inkjet-printed pattern has total thickness greater than 5 μm and not more than 250 μm; and
forming at least one reflective bottom layer by spraying at least one reflective bottom layer by the inkjet printer on one side of the dried-and-cleaned transparent substrate with the inkjet-printed pattern thereby covering the inkjet-printed pattern, wherein the reflective bottom layer is a highly-reflective paint;
wherein a central portion of the inkjet-printed pattern is thicker than a peripheral portion thereof and a thickness of the inkjet-printed pattern gradually decreases from the central portion to the peripheral portion, different amounts of light thereby pass through different portions of the inkjet-printed pattern.

7. The product as claimed in claim 6, wherein there is a plurality of layers of the inkjet-printed pattern stacked correspondingly.

8. The product as claimed in claim 6, wherein the transparent substrate is made from glass.

9. The product as claimed in claim 6, wherein the transparent substrate is selected from the group consisting of a cell phone case, a housing of consumer electronics or a dashboard.
